(19) United States
(12) Patent Application Publication
(10) Pub. No.: US 2020/0036339 A1
(43) Pub. Date: Jan. 30, 2020

(54) POWER AMPLIFIER CIRCUIT WITH DIVERTING CURRENT PATH

(71) Applicant: Avago Technologies International Sales Pte. Limited, Singapore (SG)

(72) Inventors: Michael Wendell Vice, El Granada, CA (US); Jung-Min Oh, Gangnam-gu (KR); Jung-Lin Woo, Gwanak-gu (KR); Seung-Yub Lee, Gyeonggi-do (KR)

(21) Appl. No.: 16/046,147

(22) Filed: Jul. 26, 2018

(51) Int. Cl. H03F 1/02; H03F 3/19; H03F 3/21; H03F 3/45; H03F 1/56

(52) U.S. Cl. CPC H03F 1/0233; H03F 3/19; H03F 3/21; H03F 3/4508; H03F 2203/45228; H03F 2200/451; H03F 2200/222; H03F 2200/541; H03F 2200/105; H03F 1/565

(57) ABSTRACT

A power amplifier circuit includes a coil circuit, a differential amplifier and a diverting current path. The coil circuit includes first and second coil portions coupled to a common node. The differential amplifier includes first and second transistors, each of which has first, second and third terminals. The respective first terminals of the first and second transistors are coupled to the coil circuit, and the respective third terminals of the first and second transistors are coupled to a ground terminal. The diverting current path is coupled between the common node and the ground terminal to divert portions of perturbation currents caused by a biasing voltage with a time varying magnitude at the second terminals of the first and second transistors. The diverting current path provides relatively high admittance path between the first terminals of the first and second transistors and ground, thereby reducing perturbation currents that exit the third terminals.

### BACKGROUND

Wireless communications systems are generally designed around various modulation schemes, such as orthogonal frequency-division multiplexing (OFDM) and code division multiple access (CDMA), intended to provide efficient utilization of the allocated spectrum. Spectrally efficient modulation schemes have high crest factors (e.g., peak to average power ratios). However, proper conveyance of data and acceptable spectral re-growth characteristics place a linearity burden on the transmit chain, including a power amplifier.

In order to achieve the required linearity, conventional systems typically require substantial power back-off from saturation of an output transistor in the power amplifier, which significantly reduces efficiency. In portable equipment, such as cellular telephones, reduction in efficiency translates into shorter battery life and reduced operating time between battery recharges. Generally, the industry trend is to increase the interval between battery recharges and/or to decrease the size of the batteries. Therefore, the efficiency of power amplifiers should be increased while still meeting linearity requirements.

The power amplifier of a cellular telephone uses envelope tracking to improve efficiency, resulting in longer time between battery recharges and lower operating temperature, for example. The power amplifier includes a pair of amplifying transistors that typically have a common emitter (or common source) connected to ground. By principle of operation, a time varying voltage supply (envelope tracking voltage) to the transistors varies rapidly in response to the magnitude of a modulated carrier, such as a radio frequency (RF) input signal. This results in displacement current in a base-collector capacitance (Cbc), or equivalently in a gate-drain capacitance (Cgd), of the transistors. While a portion of the displacement current of each transistor exits the base (gate), the remainder of the displacement current enters the base-emitter junction (gate-source junction), perturbing the operating point of the transistor. The time varying perturbation of the transistor operating point by a time varying envelope tracking voltage source driving the power amplifier contributes to nonlinearity, making it more difficult to meet spectral requirements of the power amplifier. Also, the magnitude of each of the displacement currents depends on the time derivative of the envelope tracking voltage, resulting in power amplifier operation that is dependent on the time derivative of the RF envelope magnitude of the RF input signal. This may result in unwanted modulation of time delay and vector gain of the power amplifier.

An additional source of unwanted displacement current may be a pair of driver transistors, connected to the bases (gates) of the pair of amplifying transistors, where the envelope tracking voltage is further used to operate the driver transistors. Additional displacement currents from the collectors (drains) of the driver transistors pass through at least a portion of a matching circuit coupling the driver transistor and the amplifying transistors, and enter the respective bases (gates) of the amplifying transistors. A portion of each of these displacement currents also enters the base-emitter junction (gate-source junction) of the respective amplifying transistor, thereby compounding the displacement current problem.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawing figures.

FIG. 1 is a simplified circuit diagram illustrating a power amplifier circuit including a diverting current path for perturbation current, according to a representative embodiment.

FIG. 2 is a simplified circuit diagram illustrating a power amplifier circuit including a diverting current path for perturbation current, according to a representative embodiment.

FIG. 3 is a simplified circuit diagram illustrating a portion of a power amplifier circuit including a diverting current path for perturbation current, according to a representative embodiment.

FIG. 4 is a simplified circuit diagram illustrating a power amplifier circuit including a diverting current path for perturbation current, according to a representative embodiment.

FIG. 5 is a simplified circuit diagram illustrating a power amplifier circuit including an optimized envelope tracking (ET) voltage circuit, according to a representative embodiment.

FIG. 6 is a simplified circuit diagram illustrating a power amplifier circuit including a diverting current path for perturbation current and a base bias circuit, according to a representative embodiment.

FIG. 7 is a simplified circuit diagram illustrating a power amplifier circuit including a base bias circuit, according to a representative embodiment.

FIG. 8 is a simplified flow diagram illustrating a method of amplifying a RF signal using an envelope tracking power amplifier circuit, according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it is understood that as used in the specification and appended claims, the terms “a”, “an” and “the” include both singular and plural referents, unless the context clearly dictates otherwise. Thus, for example, “a component” includes one component and plural components.

As used in the specification and appended claims, and in addition to their ordinary meanings, the terms “substantial” or “substantially” mean to within acceptable limits or degree. For example, the term “substantial amount” means that one skilled in the art would consider the amount to be greater than an average, and acceptable for stated purposes within the context in which the term is used. As a further example, “substantially removed” means that one skilled in the art would consider the removal to be acceptable. As used in the specification and the appended claims and in addition to its ordinary meaning, the term “approximately” means to within an acceptable limit or amount to one having ordinary skill in the art. For example, “approximately the same” means that one of ordinary skill in the art would consider the items being compared to be the same.

Envelope tracking may be used to improve amplifier efficiency. Generally, a collector supply voltage or biasing voltage, provided to amplifying transistors (e.g., output transistors) of a power amplifier (or drain supply voltage depending on the type of transistor), is modulated to provide the voltage required by a carrier envelope at each point in time, but no more. In comparison, whereas a traditional power amplifier may provide a fixed 3.3V to the collector of the output transistor at all times, the envelope tracking power amplifier may provide real time optimization of a time varying collector supply voltage, so that the collector supply voltage is sufficient, but not excessive, at all times. Envelope tracking therefore enhances efficiency, particularly at times when the carrier envelope is below maximum. Discussion of envelope tracking power amplifiers is provided, for example, by U.S. Pat. No. 9,825,616 to Vice et al. (issued Nov. 21, 2017), which is hereby incorporated by reference in its entirety. The embodiments may apply to other types of envelope tracking power amplifiers as well, such as continuous envelope tracking power amplifiers, without departing from the scope of the present teachings.

Generally, the various embodiments are directed to improving linearity in operation of a power amplifier circuit subject to a time varying voltage supply (envelope tracking voltage) that is responsive to a modulated carrier, such as an RF input signal. Portions of current flowing in an amplifying transistor that result from the time varying nature of the voltage supply (as opposed to a fixed voltage supply) may be referred to perturbation currents. The perturbation currents are in addition to normal or expected currents that flow in the amplifying transistor, e.g., when the voltage supply provides a fixed or constant voltage. For purposes of explanation, the portion of the current flowing from the collector terminal to the base terminal (through the collector-base junction) that results from the varying voltage supply may be referred to as the collector-base perturbation current (which is the same as the base-collector displacement current, discussed above) or first perturbation current. The portion of the current exiting the base terminal that results from the varying voltage supply may be referred to as the base perturbation current or second perturbation current, and the portion of the current flowing from the base terminal to the emitter terminal (through the base-emitter junction) that results from the varying voltage supply may be referred to as the base-emitter perturbation current or third perturbation current.

In various embodiments, a diverting current path may be provided at a virtual ground of the power amplifier circuit to divert to ground a portion of the collector-base perturbation current from the collector-base junction of each amplifying transistor in the power amplifier circuit. As the diverted portion of the collector-base perturbation current increases (i.e., the base perturbation current increases), a remaining portion of the collector-base perturbation current, available to enter the base-emitter junction of the amplifying transistor, decreases (i.e., the base-emitter perturbation current decreases). Linearity improves with less base-emitter perturbation current exiting the emitter terminal to ground. That is, the diverting current path must provide high enough admittance (low enough impedance) at frequencies of the displacement current to result in a substantial reduction in base-emitter perturbation current. For example, the base-emitter perturbation current may be about one half or less of what it would be without the diverting current path, according to the various embodiments. In another example, the diverting current path of the power amplifier circuit may include an optimized tracking voltage source that provides a driving voltage, as a function of an envelope tracking voltage, to drive the virtual ground. The driving voltage is optimized so that a path for the collector-base perturbation current to the virtual ground has higher effective admittance than the path through the base-emitter junction, thereby diverting a substantial portion of the collector-base perturbation current to the virtual ground (as the base perturbation current) and improving the linearity of the power amplifier circuit.

According to a representative embodiment, a power amplifier circuit includes a coil circuit for receiving a radio frequency (RF) signal, a differential amplifier and a diverting current path. The coil circuit includes a first coil portion and a second coil portion coupled to a common node of the coil circuit. The differential amplifier includes a first transistor and a second transistor, each of the first transistor and the second transistor has a first terminal, a second terminal and a third terminal, where the respective first terminals of the first transistor and the second transistor are coupled to the coil circuit, and the respective third terminals of the first transistor and the second transistor are coupled to a common ground. The diverting current path is coupled between the common node of the coil circuit and the ground terminal to divert a substantial portion of a first perturbation current caused by a biasing voltage at the second terminal of the first transistor. The diverting current path likewise diverts a substantial portion of a second perturbation current caused by the biasing voltage at the second terminal of the second transistor. The biasing voltage has a time varying magnitude according to an envelope of the RF signal, and the diverting current path is configured to provide a relatively high admittance path between the first terminal of the first transistor and the ground terminal such that the substantial portion of the first perturbation current flows through the diverting current path to the ground terminal thereby reducing another portion of the first perturbation current that exits the third terminal of the first transistor.

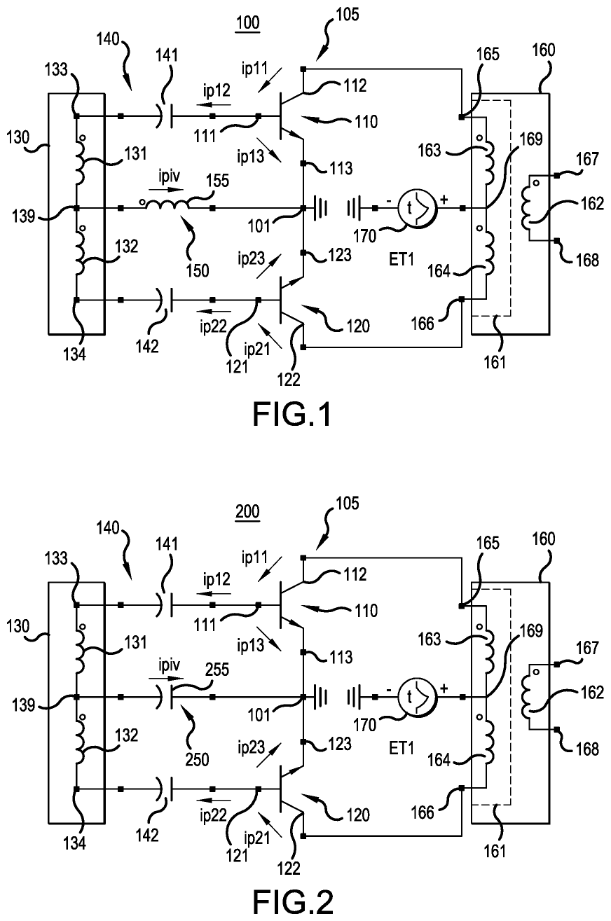

FIG. 1 is a circuit diagram illustrating a portion of a power amplifier circuit including a diverting current path for perturbation current, according to a representative embodiment.

Referring to FIG. 1, power amplifier circuit 100 includes a differential amplifier 105 including a first transistor 110 and a second transistor 120 connected at a common ground terminal 101. The first and second transistors 110 and 120 may be referred to as amplifying transistors. In the depicted embodiment each of the first and second transistors 110 and 120 is a bipolar junction transistor (BJT). Notably, the various embodiments discussed herein will reference BJTs and corresponding terminals (base, collector, emitter), for ease of explanation, although it is understood that other types of transistors may be incorporated without departing from the scope of the present teachings, such as field effect transistors (FETs) and corresponding terminals (gate, drain, source). Additional types of transistors that may be used include gallium arsenide FETs (GaAs FETs), metal-oxide semiconductor FETs (MOSFETs), heterostructure FETs (HFETs), high electron mobility transistors (HEMTs), and pseudomorphic HEMTs (pHEMTs), for example.

The first transistor 110 includes a base 111 (first terminal), a collector 112 (second terminal) and an emitter 113 (third terminal), and the second transistor 120 includes a base 121 (first terminal), a collector 122 (second terminal) and an emitter 123 (third terminal). The base 111 of the first transistor 110 and the base 121 of the second transistor 120 are coupled to a coil circuit 130, discussed below. The collector 112 of the first transistor 110 and the collector 122 of the second transistor 120 are coupled to an output transformer 160, discussed below. The emitter 113 of the first transistor 110 and the emitter 123 of the second transistor 120 are coupled directly to ground terminal 101.

The differential amplifier 105 receives an RF input signal by way of the coil circuit 130. In the depicted embodiment, the coil circuit 130 includes a first coil portion 131 and a second coil portion 132, which are electrically connected in series through a common node (e.g., centertap) 139. That is, the first coil portion 131 is connected between a first input node 133 and the common node 139 located between the first and second coil portions 131 and 132, and the second coil portion 132 is connected between a second input node 134 and the common node 139. The first and second coil portions 131 and 132 may include first and second inductances, respectively, which may be substantially similar so that the common node 139 corresponds to a center of the coil circuit 130. So, for example, the first and second coil portions 131 and 132 may be provided by centertapping a single inductor (used in a conventional power amplifier). By symmetry, the common node 139 may be a virtual ground of the power amplifier circuit 100. That is, a first inductance of the first coil portion 131 and a second inductance of the second coil portion 132 provide a virtual ground voltage for the RF input signal at the common node 139. In various configurations, the first coil portion 131 and/or the second coil portion 132 may comprise one or more inductors, for example. The first input node 133 and the second input node 134 of the coil circuit 130 may correspond to differential input ports for the differential amplifier 105 to receive the RF input signal. Also, the coil circuit 130 may be a secondary winding of an input transformer, as discussed below with reference to FIG. 4, for example.

A matching network 140 is included between the differential amplifier 105 and the coil circuit 130, such that the first transistor 110 and the second transistor 120 are coupled to the coil circuit 130 through the matching network 140. The matching network 140 is configured to match impedances of the differential amplifier 105 and the coil circuit 130. In the depicted embodiment, the matching network 140 includes a first capacitor 141 connected between the base 111 of the first transistor 110 and the first input node 133 of the coil circuit 130, and a second capacitor 142 connected between the base 121 of the second transistor 120 and the second input node 134 of the coil circuit 130. The first and second coil portions 131 and 132 of the coil circuit 130 may also be taken into consideration as part of the matching network 140. The matching network 140 may include alternative or additional components to achieve impedance matching between the coil circuit 130 and the differential amplifier 105, without departing form the present teachings.

The power amplifier circuit 100 further includes an output transformer 160, which has a primary winding 161 and a secondary winding 162 providing an output of the power amplifier circuit 100. The primary winding 161 may include multiple coil circuits, such as first coil circuit 163 and second coil circuit 164. The first coil circuit 163 is connected between a first output node 165 and a common node (centertap) 169, and the second coil circuit 164 is connected between a second output node 166 and the common node 169. In the depicted embodiment, the secondary winding 162 is a single coil circuit connected between signal output ports 167 and 168, although the secondary winding 162 may include multiple coil circuits in series without departing from the scope of the present teachings. The power amplifier circuit 100 is configured to amplify an RF input signal received through a signal input port (not shown) and the first and second input nodes 133 and 134 of the coil circuit 130, and to output an amplified RF output signal from signal output ports 167 and 168.

An envelope tracking (ET) voltage source 170 is connected between ground and the common node 169 of the secondary winding 162. The ET voltage source 170 provides a tracking voltage that serves as a biasing voltage for biasing the collectors 112 and 122 of the first and second transistors 110 and 120, respectively. The tracking voltage has a time varying magnitude that varies according to an envelope of the RF input signal.

With respect to the first transistor 110, a positive time derivative of the biasing voltage causes a current, referred to as first collector-base perturbation current (ip11), to enter the collector-base junction at the collector 112. A portion of the first collector-base perturbation currentip12 exits the base 111 as first base perturbation current (ip12) and flows to the coil circuit 130 through the first capacitor 141. A remaining portion of the first collector-base displacement currentip13 enters the base-emitter junction of the first transistor 110 as first base-emitter perturbation current (ip13) and exits the emitter 113 to the ground terminal 101. Similarly, with respect to the second transistor 120, a positive time derivative of the biasing voltage causes a current, referred to as second collector-base perturbation current (ip21), to enter the collector-base junction at the collector 122. A portion of the second collector-base displacement currentip22 exits the base 121 as second base perturbation current (ip22) and flows to the coil circuit 130 through the second capacitor 142. A remaining portion of the second collector-base displacement currentip23 enters the base-emitter junction of the second transistor 120 as second base-emitter perturbation current (ip23) and exits the emitter 123 to the ground terminal 101.

As indicated above, the first and second base-emitter perturbation currents generally perturb the operating point of the first and second transistors 110 and 120, respectively, causing unwanted gain perturbations. The time varying perturbations of the transistor operating points contribute to nonlinearity, making it more difficult to meet spectral requirements of the power amplifier circuit 100. It is therefore advantageous to minimize the first and second base-emitter perturbation currents (ip13, ip23). This may be accomplished by diverting as much of the first and second collector-base perturbation currents (ip11, ip21) away from the bases 111 and 121 as possible. In other words, the first and second base perturbation currents (ip12, ip22) should be increased, while the first and second base-emitter perturbation currents (ip13, ip23) should be decreased.

In order to increase the first and second base perturbation currents (ip12, ip22) relative to the first and second base-emitter perturbation currents (ip13, ip23), a diverting current path 150 is coupled between the common node 139 (e.g., virtual ground) of the coil circuit 130 and the ground terminal 101. The diverting current path 150 is configured to conduct a diverted current (idiv) from the common node 139 to the ground terminal 101, where the diverted current (idiv) comprises at least a portion of each of the first and second base perturbation currents (ip12, ip22). The diverting current path 150 may include a passive component, for example, which in the depicted embodiment is an inductance 155. Additional passive components may be included in the diverting current path 150, including additional inductor(s), or the diverting current path 150 may be a short circuit, as appropriate or suitable in various implementations or applications, without departing from the scope of the present teachings.

The admittance of the diverting current path 150 is relatively high, e.g., as compared to the admittance between the base-emitter junctions of the first and second transistors 110 and 120, such that the common node 139 provides a substantial common mode ground. That is, the relatively high admittance of the diverting current path 150 approaches that of a short circuit (e.g., having a corresponding impedance of about zero). For example, the diverting current path 150 may provide the relatively high admittance path at a predetermined frequency that correlates with a baseband frequency of interest of an RF signal in a telecommunication system that includes the power amplifier circuit 100. Accordingly, substantial portions of the first collector-base perturbation current (ip11) and the second collector-base perturbation current (ip21) flow from the bases 111 and 121 as the first and second base perturbation currents (ip12, ip22), respectively, and through the diverting current path 150 as the diverted current (idiv) to the ground terminal 101. A substantial portion of each of the first collector-base perturbation current (ip11) and the second collector-base perturbation current (ip21) may refer to at least half, for example, of each of the first and second collector-base perturbation currents (ip11, ip21) being diverted. A substantial portion of each of the first collector-base perturbation current (ip11) and the second collector-base perturbation current (ip21) may refer to more than substantially more than half, further improving linearity of the power amplifier circuit 100.

Therefore, an alternative current path to the ground terminal 101 exists for the first and second collector-base perturbation currents (ip11, ip21), in which the admittance for the first and second collector-base perturbation currents (ip11, ip21) is increased by the presence of the diverting current path 150 (e.g., the inductance 155). The result is an increase in magnitude of the first and second base perturbation currents (ip12, ip22) (and thus the magnitude of the diverted current (idiv)), and a corresponding decrease in magnitude of the first and second base-emitter perturbation currents (ip13, ip23). Accordingly, the power amplifier circuit 100 will operate more linearly with the inclusion of the diverting current path 150 than without the diverting current path 150, all other things being equal.

FIG. 2 is a simplified circuit diagram illustrating a power amplifier circuit including a diverting current path for perturbation current, according to a representative embodiment. Referring to FIG. 2, power amplifier circuit 200 is substantially the same as the power amplifier circuit 100 discussed above, except that the passive component in diverting current path 250 includes a single capacitor 255 as opposed to the inductance 155. Additional passive components may be included in the diverting current path 250, including additional capacitor(s), as appropriate or suitable in various implementations or applications, without departing from the scope of the present teachings. Again, the admittance of the diverting current path 250 is relatively high, e.g., as compared to the admittance between at the base-emitter junctions of the first and second transistors 110 and 120, such that the common node 139 provides a substantial common mode ground. Thus, the magnitudes the first and second base perturbation currents (ip12, ip22) increase, while the first and second base-emitter perturbation currents (ip13, ip23) decrease.

In alternative embodiments, the capacitor 255 in FIG. 2 and/or the inductance 155 in FIG. 1 may be replaced with other passive components, such as one or more resistors, or replaced with combinations of passive components, to provide unique benefits for any particular situation or to meet application specific design requirements of various implementations, as would be apparent to one skilled in the art. In still other embodiments, the capacitor 255 in FIG. 2 and/or the inductance 155 in FIG. 1 may be replaced with a direct short to the ground terminal 101. The selection of components and/or network to provide the current diverting function depends on the circuit tolerance. For instance, a direct short between the common node 139 and the ground terminal 101 may result in unwanted second order effects, such as stability degradation in the power amplifier circuit. In this case, a small amount of inductance or series connected inductance and resistance (L-R) may be sufficient to restore original performance of the power amplifier circuit, while providing the diverting current path.

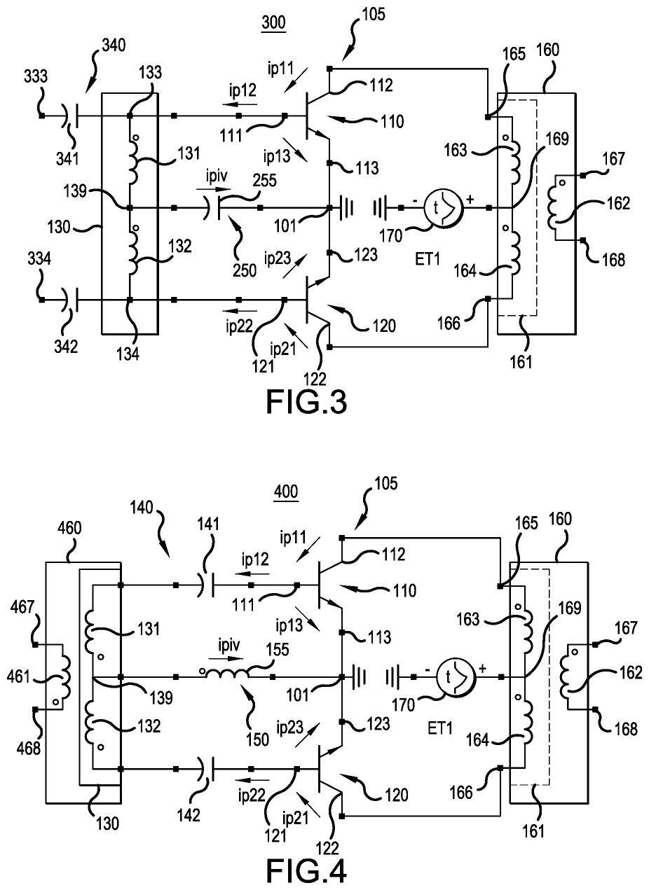

FIG. 3 is a simplified circuit diagram illustrating a portion of a power amplifier circuit including a diverting current path for perturbation current, according to a representative embodiment. Referring to FIG. 3, power amplifier circuit 300 is substantially the same as the power amplifier circuit 200 discussed above, except for placement of the matching circuit. That is, the matching network 140 is replaced by a matching network 340, which is positioned on an opposite side of the coil circuit 130, away from the differential amplifier 105. The matching network 340 includes a first capacitor 341 connected between the first input node 133 of the coil circuit 130 and a first input port 333, and a second capacitor 342 connected between the second input node 134 of the coil circuit 130 and a second input port 334. The first and second coil portions 131 and 132 may also be taken into consideration as part of the matching network 340. Still, as discussed above, the admittance of the diverting current path 250 is relatively high, e.g., as compared to the admittance between at the base-emitter junctions of the first and second transistors 110 and 120, such that the common node 139 provides a substantial common mode ground. Thus, the magnitudes of the first and second base perturbation currents (ip12, ip22) increase, while the first and second base-emitter perturbation currents (ip13, ip23) decrease.

In alternative configurations, the matching network 340 may replace the matching network 140 of the power amplifier circuit 100 as shown in FIG. 1, where the diverting current path 150 includes the inductance 155. Also, the matching network 340 may include alternative or additional components to achieve impedance matching between the coil circuit 130 and the differential amplifier 105, without departing form the present teachings.

FIG. 4 is a simplified circuit diagram illustrating a power amplifier circuit including a diverting current path for perturbation current, according to a representative embodiment. Referring to FIG. 4, power amplifier circuit 400 is substantially the same as the power amplifier circuit 100 in FIG. 1 discussed above, except that the coil circuit 130 is specifically shown as a secondary winding of an input transformer 460. The input transformer 460 therefore includes a primary winding 461 and a secondary winding implemented by the coil circuit 130 providing the input to the differential amplifier 105. The primary winding 461 may include a single coil circuit connected between signal input ports 467 and 468, although the primary winding 461 may include multiple coil circuits in series without departing from the scope of the present teachings. The power amplifier circuit 400 is configured to amplify an RF input signal received through the signal input ports 467 and 468 of the primary winding 461.

As discussed above, the coil circuit 130 includes the first coil portion 131 connected between the first input node 133 and the common node 139, and the second coil portion 132 connected between the second input node 134 and the common node 139. The first inductance of the first coil portion 131 and the second inductance of the second coil portion 132 provide a virtual ground voltage for the RF input signal at the common node 139. Of course, one or both of the first and second coil portions 131 and 132 may comprise one or more inductors, for example, without departing from the scope of the present teachings.

FIG. 5 is a simplified circuit diagram illustrating a power amplifier circuit including an optimized ET voltage circuit, according to a representative embodiment. Referring to FIG. 5, power amplifier circuit 500 is substantially the same as the power amplifier circuit 400 in FIG. 4 discussed above, except that diverting current path 550 is an optimized ET voltage circuit including an optimized ET voltage source 555 connected between ground and the common node 139 of the secondary winding (coil circuit 130). The diverting current path 550 increases the effective admittance at baseband frequencies of the RF signal for the first and second base perturbation currents ip12 and ip22, beyond what would be provided by placing a ground voltage at the common node 139 or by shorting the common node 139 to ground. It is possible to mitigate the impedance of the matching network 140 in series with the first and second coil portion 131 and 132 by providing a voltage at the common node 139 which is the product of a and Vet1, for example, where a is an optimized complex number and Vet1 is the tracking voltage provided by the ET voltage source 170.

The optimized ET voltage source 555 provides a driving voltage to drive the virtual ground at the common node 139 to increase the effective admittance to ground for first and second base perturbation currents ip12 and ip22. The driving voltage is a function of the tracking voltage of the ET voltage source 170. For example, the driving voltage provided by the optimized ET voltage source 555 may be a linear combination of the tracking voltage provided by the ET voltage source 170 and its time derivative. Other functional relationships of the driving voltage to the tracking voltage may be incorporated, without departing from the scope of the present teachings.

The driving voltage is then coupled to the virtual ground at the common node 139, and the exact value of the driving voltage is optimized, e.g., empirically, to improve the linearity of the power amplifier circuit 500 when operating in envelope tracking mode. The linearity is improved by reducing the magnitudes of the first and second base-emitter perturbation currents (ip13, ip23), as in the previous embodiments. Optimizing the driving voltage provides paths (e.g., through the matching network 140) for a portion of each of the first and second collector-base perturbation currents (ip11, ip21) to ground, where the paths have higher admittance than the base-emitter junctions of the first and second transistors 110 and 120. Accordingly, substantial portions of the first and second collector-base perturbation currents (ip11, ip21) flow to ground (as opposed to the emitters 113, 123), thereby improving the linearity of the power amplifier circuit 500. The diverting current path 550 may be implemented in place of the diverting current paths 150 or 250 in any of the topologies depicted in FIGS. 1-3 having the virtual ground at the common node 139.

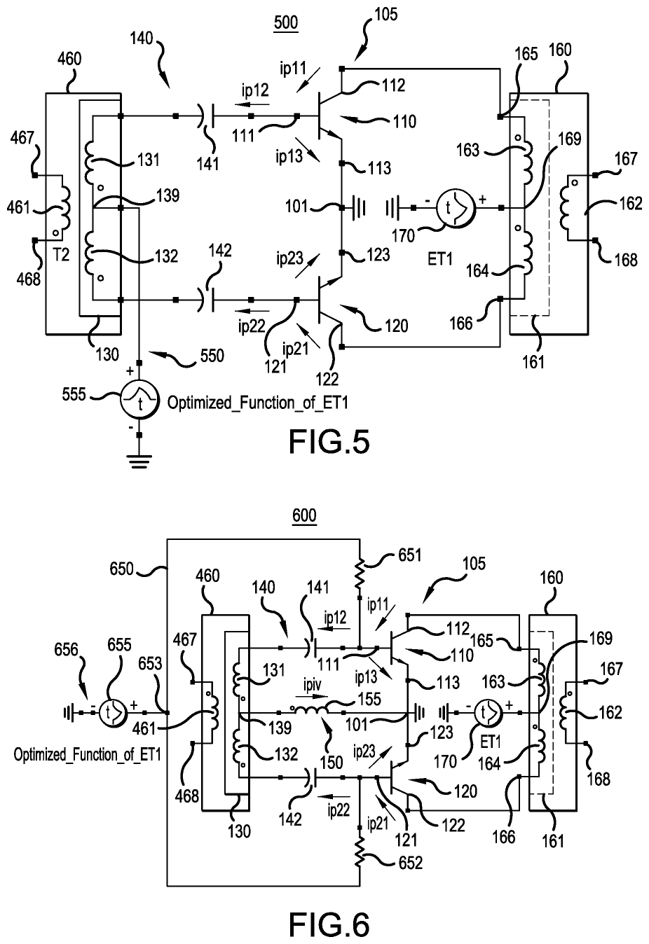

FIG. 6 is a simplified circuit diagram illustrating a power amplifier circuit including a base bias circuit, in addition to the diverting current path, according to a representative embodiment. Referring to FIG. 6, power amplifier circuit 600 is substantially the same as the power amplifier circuit 400 in FIG. 4, discussed above, with the addition of the base bias circuit 650. In the depicted embodiment, the base bias circuit 650 includes an optimized ET voltage source 655, a first resistance connected between the base 111 of the first transistor 110 and the optimized ET voltage source 655, and a second resistance 652 connected between the base 121 of the second transistor 120 and the optimized ET voltage source 655. In alternative configurations, the first and second resistances 651 and 651 may be replaced by capacitances or inductances. The optimized ET voltage source 655 is connected between ground and a common bias node 653 of the base bias circuit 650.

The optimized ET voltage source 655 provides a driving voltage to drive the common bias node 653. The driving voltage is a function of the tracking voltage of the ET voltage source 170. For example, the driving voltage provided by the optimized ET voltage source 655 may be a linear combination of the tracking voltage provided by the ET voltage source 170 and its time derivative. Other functional relationships of the driving voltage to the tracking voltage may be incorporated, without departing from the scope of the present teachings.

The exact value of the driving voltage is optimized, e.g., empirically, to improve linearity of the power amplifier circuit 600, and/or the first and second transistors 110 and 120, when operating in envelope tracking mode by coupling the driving voltage to the bases 111 and 121 of the first and second transistors 110 and 120. The non-linearity caused by the portion of the collector-base perturbation current (ip11, ip21) entering the base-emitter junctions of the first and second transistors 110 and 120 may be partially cancelled by the improvement in linearity introduced by the base bias circuit 650. For example, when optimized, the driving voltage effectively causes the base bias circuit 650 to compensate for residual perturbation current in the base-emitter junctions by imposing a compensating non-linearity in the form of bias perturbation. The base bias circuit 650 may be implemented in any of the topologies depicted in FIGS. 1-4.

The base bias circuit 650 functions in conjunction with the diverting current path 150 coupled between the common node 139 and the ground terminal 101, which continues to enable the flow of diverted current (idiv) from the common node 139 to the ground terminal 101, where the diverted current (idiv) includes at least a portion of each of the first and second base perturbation currents (ip12, ip22). As discussed above, the diverted current (idiv) decreases the portion of the collector-base perturbation currents (ip11, ip21) that pass through the base-emitter junctions of the first and second transistors 110 and 120, thereby lowering the respective base-emitter perturbation currents (ip13, ip23) and further reducing non-linearity.

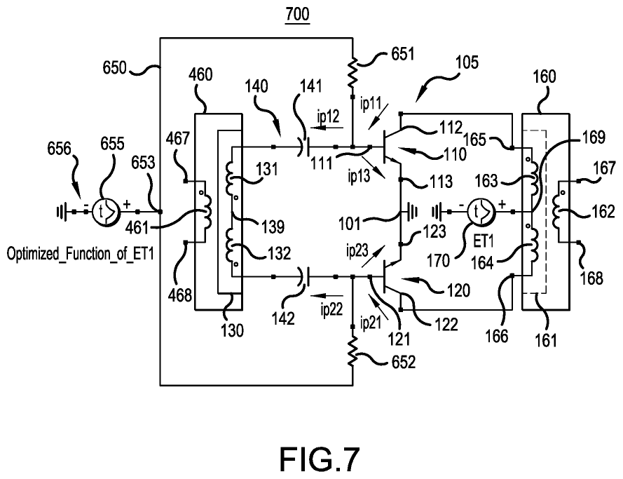

FIG. 7 is a simplified circuit diagram illustrating a power amplifier circuit including a base bias circuit, according to a representative embodiment. Referring to FIG. 7, power amplifier circuit 700 is substantially the same as the power amplifier circuit 600 in FIG. 6, discussed above, without diverting current path 150 (and inductance 155) coupled between the common node 139 and the ground terminal 101. Accordingly, there is no diverted current (idiv), including at least a portion of each of the first and second base perturbation currents (ip12, ip22), from the common node 139 to the ground terminal 101. Regardless, the base bias circuit 650 still improves linearity of the power amplifier circuit 700. That is, the optimized ET voltage source 655, which is a function of the tracking voltage of the ET voltage source 170, provides a driving voltage to drive the common bias node 653. The value of the driving voltage may optimized, e.g., empirically, to improve the linearity of the power amplifier circuit 600 when operating in envelope tracking mode.

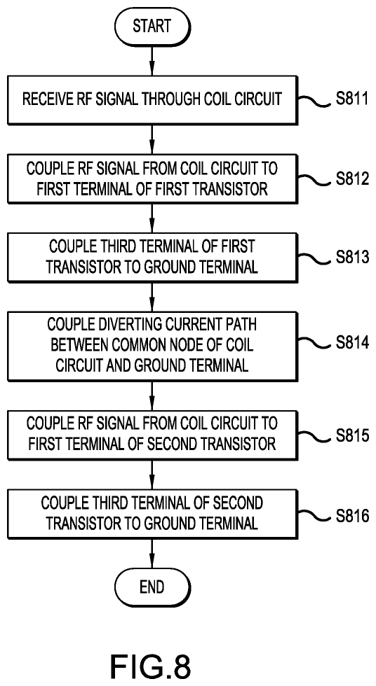

FIG. 8 is a simplified flow diagram illustrating a method of amplifying an RF signal using an envelope tracking power amplifier circuit, according to a representative embodiment. The power amplifier circuit includes at least a first transistor having a first terminal, a second terminal and a third terminal. Referring to FIG. 8, a method is provided for amplifying the RF signal using an envelope tracking power amplifier circuit, such as any of the power amplifier circuits 100-600, discussed above. The power amplifier circuit includes a coil circuit for receiving the RF signal and an amplifier. The coil circuit includes a common node, and first and second coil portions coupled to the common node. The amplifier may be a differential amplifier that includes at least a first transistor and a second transistor, each of which has a first terminal (e.g., base), a second terminal (e.g., collector) and a third terminal (e.g., emitter).

The method includes receiving the RF signal at block S811 through the coil circuit, and coupling the RF signal from the coil circuit to the first terminal of the first transistor at block S812. The third terminal of the first transistor is coupled to a ground terminal at block S813, and a diverting current path is coupled between a common node of the coil circuit and the ground terminal at block S814. Coupling of the diverting current path diverts a first portion of a first perturbation current, e.g., at the collector-base junction of the first transistor, caused by a biasing voltage at the second terminal of the first transistor. Likewise, the method may further include, at substantially the same time, coupling the RF signal from the coil circuit to the first terminal of the second transistor at block S815, and coupling the third terminal of the second transistor to the ground terminal at block S816. The diverting current path coupled between the common node of the coil circuit and the ground terminal also diverts a first portion of a second perturbation current, e.g., at the collector-base junction of the second transistor, caused by the biasing voltage at the second terminal of the second transistor. The biasing voltage has a time varying magnitude related to an envelope of the RF signal.

Coupling the diverting current path between the common node of the coil circuit and the ground terminal provides a relatively high admittance path between each of the first terminals of the first and second transistors and the ground terminal. Therefore, the first portions of the first and second perturbation currents flow through the diverting current path thereby reducing second portions of the first and second perturbation current that exit the third terminal of the first and second transistors, respectively. Coupling the diverting current path may include electrically coupling a first end of a passive component(s) (e.g., inductor, capacitor and/or resistor) to the common node of the coil circuit, and a second end of the passive component to the ground terminal.

As mentioned above, for purposes of discussion, terms typically corresponding to BJTs, such as emitter, collector and base, are used herein to describe FIGS. 1-8. However, it is understood that these terms are not intended to be limiting, and that terms corresponding to FETs, such as drain, source and gate, would be applicable for other types of transistors in various alternative configurations.

The driving voltage values of the optimized ET voltage sources 555 and 655 may be set, optimized and/or monitored by a controller (not shown) comprising a computer processor and memory, for example. In various embodiment, the processor may be implemented by a computer processor, a microprocessor, application-specific integrated circuits (ASICs), field-programmable gate arrays (FPGAs), other forms of circuitry configured for this purpose, or combinations thereof, using software, firmware, hard-wired logic circuits, or combinations thereof. A computer processor, in particular, may be constructed of any combination of hardware, firmware or software architectures, and may include memory (e.g., volatile and/or nonvolatile memory) for storing executable software/firmware executable code that allows it to perform the various functions.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A power amplifier circuit comprising:
a coil circuit for receiving a radio frequency (RF) signal, wherein the coil circuit comprises a first coil portion and a second coil portion coupled to a common node of the coil circuit;
a differential amplifier comprising a first transistor and a second transistor, each of the first transistor and the second transistor has a first terminal, a second terminal and a third terminal, wherein the respective first terminals of the first transistor and the second transistor are coupled to the coil circuit, and the respective third terminals of the first transistor and the second transistor are coupled to ground; and
a diverting current path coupled between the common node of the coil circuit and ground to divert a substantial portion of a first perturbation current caused by a biasing voltage at the second terminal of the first transistor, wherein:
the biasing voltage has a time varying magnitude according to an envelope of the RF signal, and
the diverting current path is configured to provide a relatively high admittance path between the first terminal of the first transistor, such that the substantial portion of the first perturbation current flows through the diverting current path to ground thereby reducing another portion of the first perturbation current that exits the third terminal of the first transistor.

2. The power amplifier circuit of claim 1, wherein the diverting current path comprises a passive component circuit coupled between the common node of the coil circuit and ground.

3. The power amplifier circuit of claim 1, wherein the diverting current path comprises a passive component circuit which includes an inductor, a capacitor, a resistor or a combination thereof such that the diverting current path provides the relatively high admittance path at a predetermined frequency that correlates with a baseband frequency of interest in a telecommunication system.

4. The power amplifier circuit of claim 1, wherein the diverting current path directly connects the common node of the coil circuit to ground.

5. The power amplifier circuit of claim 1, wherein the first coil portion comprises a first inductance and the second coil portion comprises a second inductance, and wherein the first inductance and the second inductance provide a virtual ground voltage for the RF signal at the common node.

6. The power amplifier circuit of claim 5, wherein the first coil portion and the second coil portion form a portion of a transformer.

7. The power amplifier circuit of claim 1, further comprising:
a transformer comprising a primary winding for receiving an RF signal input signal, and a secondary winding comprising the coil circuit,
wherein the diverting current path comprises an optimized envelope tracking voltage source connected between the common node of the coil circuit and ground, the optimized envelope tracking voltage source providing a driving voltage to drive a virtual ground at the common node to increase effective admittance between at least the first terminal of the first transistor and ground at base band frequencies of the RF signal.

8. The power amplifier circuit of claim 1 further comprising a matching network between the differential amplifier and the coil circuit, wherein the diverting current path and the matching network are configured to provide a first voltage to the first terminal of the first transistor in accordance with changes of the biasing voltage at the second terminal of the first transistor.

9. The power amplifier circuit of claim 8, wherein the diverting current path and the matching network are further configured to provide a second voltage to the first terminal of the second transistor in accordance with changes of the biasing voltage at the second terminal of the second transistor.

10. The power amplifier circuit of claim 9, wherein the matching network comprises first and second passive components coupled between the first terminal of the first transistor and the first terminal of the second transistor and the coil circuit, respectively.

11. The power amplifier circuit of claim 1, wherein:
the biasing voltage further causes a second perturbation current at the second terminal of the second transistor; and
the diverting current path is configured to further provide a relatively high admittance path between the first terminal of the second transistor and ground such that a substantial portion of the second perturbation current flows through the diverting current path to ground thereby reducing another portion of the second perturbation current that exits the third terminal of the second transistor.

12. The power amplifier circuit of claim 11, further comprising:
a base bias circuit comprising a common bias node, an optimized envelope tracking voltage source connected between the common bias node and ground, a first passive component connected between the first terminal of the first transistor and the common bias node, and a second passive component connected between the first terminal of the second transistor and the common bias node,
wherein the optimized tracking voltage source provides a driving voltage to drive the common bias node as a function of the time varying magnitude of the biasing voltage, providing a compensating non-linearity in the first and second transistors.

13. The power amplifier circuit of claim 12, further comprising a transformer having a primary winding, for receiving an RF input signal, and a secondary winding, wherein the secondary winding comprises the coil circuit.

14. A method for amplifying a radio frequency (RF) signal using an envelope tracking power amplifier circuit comprising at least a first transistor having a first terminal, a second terminal and a third terminal, the method comprising:
receiving the RF signal using a coil circuit;
coupling the RF signal from the coil circuit to the first terminal of the first transistor;
coupling the third terminal of the first transistor to a ground terminal; and
coupling a diverting current path between a common node of the coil circuit and the ground terminal to divert a portion of a first perturbation current caused by a biasing voltage at the second terminal of the first transistor, wherein:
the biasing voltage has a time varying magnitude related to an envelope of the RF signal, and
coupling the diverting current path provides a relatively high admittance path between the first terminal of the first transistor and the ground terminal such that a first portion of the first perturbation current flows through the diverting current path thereby reducing a second portion of the first perturbation current that exits the third terminal of the first transistor.

15. The method of claim 14, wherein coupling the diverting current path comprises electrically coupling a first end of an inductor to the common node of the coil circuit, and a second end of the inductor to the ground terminal.

16. The method of claim 14, wherein the coil circuit comprises a first coil portion and a second coil portion electrically connected in series through the common node of the coil circuit, and
wherein the first coil portion has a first inductance and the second coil portion has a second inductance which is substantially similar to the first inductance so that the common node of the coil circuit corresponds to a center of the coil circuit.

17. The method of claim 14, wherein the diverting current path comprises at least one of an inductor, a capacitor and a resistor such that the diverting current path provides the relatively high admittance path at a predetermined frequency of a baseband of the RF signal.

18. The method of claim 14, further comprising:
coupling the RF signal from the coil circuit to a first terminal of a second transistor;
coupling a third terminal of the second transistor to the ground terminal; and
diverting a second perturbation current caused by the biasing voltage at a second terminal of the second transistor through the diverting current path, wherein the diverting current path provides a relatively high admittance path between the first terminal of the second transistor and the ground terminal such that a first portion of the second perturbation current flows through the diverting current path thereby reducing a second portion of the second perturbation current that exits the third terminal of the second transistor.

19. A power amplifier circuit comprising:
a transformer comprising a primary winding for receiving a radio frequency (RF) signal, and a secondary winding having a first coil portion and a second coil portion coupled to a common node;
a differential amplifier comprising a first transistor and a second transistor, each of the first transistor and the second transistor having a first terminal, a second terminal and a third terminal, wherein the respective first terminals of the first transistor and the second transistor are coupled to the secondary winding via a matching network, the respective second terminals of the first transistor and the second transistor receive a biasing voltage having a time varying magnitude according to an envelope of the RF signal, and the respective third terminals of the first transistor and the second transistor are coupled to ground; and
a base bias circuit comprising a common bias node, an optimized envelope tracking voltage source connected between the common bias node and ground, a first passive component connected between the first terminal of the first transistor and the common bias node, and a second passive component connected between the first terminal of the second transistor and the common bias node,
wherein the optimized tracking voltage source provides a driving voltage to drive the common bias node as a function of the time varying magnitude of the biasing voltage, providing a compensating non-linearity in the first and second transistors.

20. The power amplifier circuit of claim 19, further comprising:
a diverting current path coupled between the common node of the transformer and ground, diverting a first portion of a first perturbation current caused by the biasing voltage at the second terminal of the first transistor, and diverting a first portion of a second perturbation current caused by the biasing voltage at the second terminal of the second transistor.
